(19) United States
(12) Patent Application Publication
(10) Pub. No.: US 2026/0164573 A1
(43) Pub. Date: Jun. 11, 2026

(54) DISPLAY DEVICE

(71) Applicant: LG ELECTRONICS INC., Seoul (KR)

(72) Inventors: Joonsub Bae, Seoul (KR); Kiyoon Nam, Seoul (KR); Kwanghun Yun, Seoul (KR); Youngkeun Choi, Seoul (KR)

(73) Assignee: LG ELECTRONICS INC., Seoul (KR)

(21) Appl. No.: 19/414,864

(22) Filed: Dec. 10, 2025

(30) Foreign Application Priority Data
Dec. 11, 2024 (WO) PCT/KR2024/096745

(51) Int. Cl. H05K 5/02

(52) U.S. Cl. CPC H05K 5/0217

(57) ABSTRACT

A display device is disclosed. The display device may include: a display panel; a frame disposed behind the display panel; and a side frame disposed along an edge of the frame, wherein the side frame may include: a first part covering the edge of the frame; and a second part intersecting the first part and disposed between the frame and the display panel; wherein the frame may include: a rear part disposed behind the second part; a middle part which is bent from an end of the rear part and which faces a front surface of the rear part; and a front part which is bent from an end of the middle part and which faces the display panel, and wherein the second part is inserted between the middle part and the front part.

### CROSS-REFERENCE TO RELATED APPLICATION

This application claims the priority benefit of International Application No. PCT/KR2024/096745, filed on Dec. 11, 2024, the disclosure of which is incorporated herein by reference.

### BACKGROUND OF THE INVENTION

### Field of the invention

The present disclosure relates to a display device.

### Description of the Related Art

With the development of information society, demand for various kinds of display devices is increasing. In response to this demand, various kinds of display devices, such as LCDs (Liquid Crystal Displays), PDPs (Plasma Display Panels), ELDs (Electro-luminescent Displays), VFDs (Vacuum Fluorescent Displays) and OLEDs (Organic Light-Emitting Diodes) have been recently researched and used.

Thereamong, display devices utilizing organic light emitting diodes have superior brightness and viewing angle to liquid crystal display devices and do not require a backlight unit, thereby enabling realization of an ultra-thin display device.

In recent years, a great deal of research on a display device having a thin thickness is being conducted according to development of display devices and consumption trends.

### SUMMARY OF THE INVENTION

It is an objective of the present disclosure to solve the above and other problems.

Another object of the present disclosure may be to provide a structure configured to couple the side frame to the frame without using an additional adhesive member.

Another object of the present disclosure may be to provide a structure configured to detachably couple the side frame to the frame.

Another object of the present disclosure may be to provide a display device having a peripheral portion having a thin thickness.

Another object of the present disclosure may be to provide a display device which includes a side portion having improved rigidity.

Another object of the present disclosure may be to provide a display device having improved torsional rigidity.

In order to accomplish the above and other objects, a display device according to one aspect of the present disclosure may include: a display panel; a frame disposed behind the display panel; and a side frame disposed along an edge of the frame, wherein the side frame may include: a first part covering the edge of the frame; and a second part intersecting the first part and disposed between the frame and the display panel, wherein the frame may include: a rear part disposed behind the second part; a middle part which is bent from an end of the rear part and which faces a front surface of the rear part; and a front part which is bent from an end of the middle part and which faces the display panel, and wherein the second part is inserted between the middle part and the front part.

### BRIEF DESCRIPTION OF THE DRAWINGS

The above and other objects, features and other advantages of the present disclosure will be more clearly understood from the following detailed description taken in conjunction with the accompanying drawings, in which:

FIGS. 1 to 13 are diagrams illustrating examples of a display device according to embodiments of the present disclosure.

### DETAILED DESCRIPTION

A description will now be given in detail according to exemplary embodiments disclosed herein, with reference to the accompanying drawings. For the sake of brevity of description with reference to the drawings, the same or equivalent components are denoted by the same reference numbers, and a description thereof will not be repeated.

In general, suffixes such as “module” and “unit” may be used to refer to elements or components. The use of such suffixes herein is merely intended to facilitate description of the specification, and the suffixes do not have any special meaning or function.

In the present disclosure, that which is well known to one of ordinary skill in the relevant art has generally been omitted for the sake of brevity. The accompanying drawings are used to facilitate understanding of various technical features, and it should be understood that the embodiments presented herein are not limited by the accompanying drawings. As such, the present disclosure should be construed to extend to any alterations, equivalents and substitutes, in addition to those that are particularly set out in the accompanying drawings.

It is to be understood that, although the terms “first,” “second,” etc. may be used herein to describe various elements, these elements should not be limited by these terms. These terms are only used to distinguish one element from another.

It will be understood that when an element is referred to as being “connected to” another element, intervening elements may be present. In contrast, it will be understood that when an element is referred to as being “directly connected to” another element, there are no intervening elements present.

A singular representation may include a plural representation unless the context clearly indicates otherwise.

In the present disclosure, it should be understood that the terms “comprises,” “includes,” “has,” etc. specify the presence of features, numbers, steps, operations, elements, components, or combinations thereof described in the specification, but do not preclude the presence or addition of one or more other features, numbers, steps, operations, elements, components, or combinations thereof.

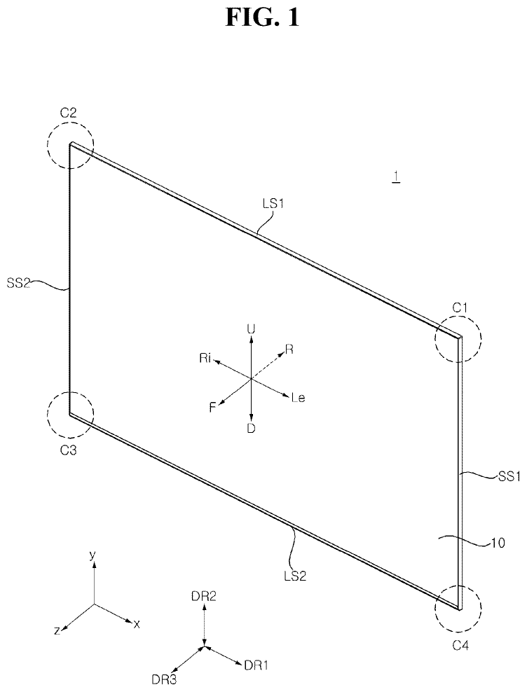

Referring to FIG. 1, the display device 1 may include a display 10. The display 10 may display an image.

The display device 1 may include a first long side LS1, a second long side LS2 opposed to the first long side LS1, a first short side SS1 adjacent to the first long side LS1 and the second long side LS2, and a second short side SS2 opposed to the first short side SS1. Although each of the first and second long sides LS1 and LS2 is illustrated and described as being longer than each of the first and second short sides SS1 and SS2 for convenience of explanation, the length of each of the first and second long sides LS1 and LS2 may be almost equal to that of each of the first and second short sides SS1 and SS2.

A direction parallel to the first and second long sides LS1 and LS2 of the display device 1 may be referred to as a lateral direction or a first direction DR1. A direction parallel to the first and second short sides SS1 and SS2 of the display device 1 may be referred to as a vertical direction or a second direction DR2. A direction perpendicular to the first and second long sides LS1 and LS2 and the first and second short sides SS1 and SS2 of the display device 1 may be referred to as a forward/backward direction or a third direction DR3.

A direction in which the display panel 10 displays an image may be referred to as forward F or z, and the opposite direction may be referred to as rearward R. The first long side LS1 may be referred to as an upper side U or y, and the second long side LS2 may be referred to as a lower side. The first short side SS1 may be referred to as a left side Le or x, and the second short side SS2 may be referred to as a right side Ri.

The first long side LS1, the second long side LS2, the first short side SS1 and the second short side SS2 may be referred to as an edge of the display device 1. The points at the first long side LS1, the second long side LS2, the first short side SS1 and the second short side SS2 meet each other may be referred to as corners.

For example, the point at which the first short side SS1 and the first long side LS1 meet each other may be referred to as a first corner C1. The point at which the first long side LS1 and the second short side SS2 meet each other may be referred to as a second corner C2. The point at which the second short side SS2 and the second long side LS2 meet each other may be referred to as a third corner C3. The point at which the second long side LS2 and the first short side SS1 meet each other may be referred to as a fourth corner C4.

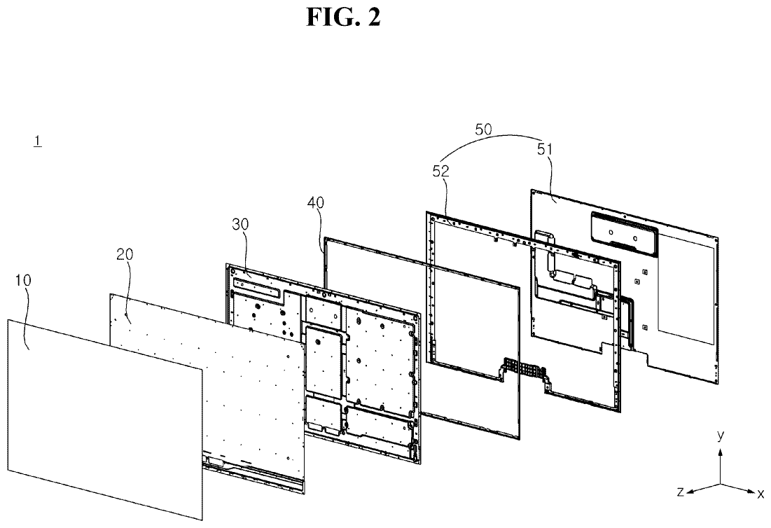

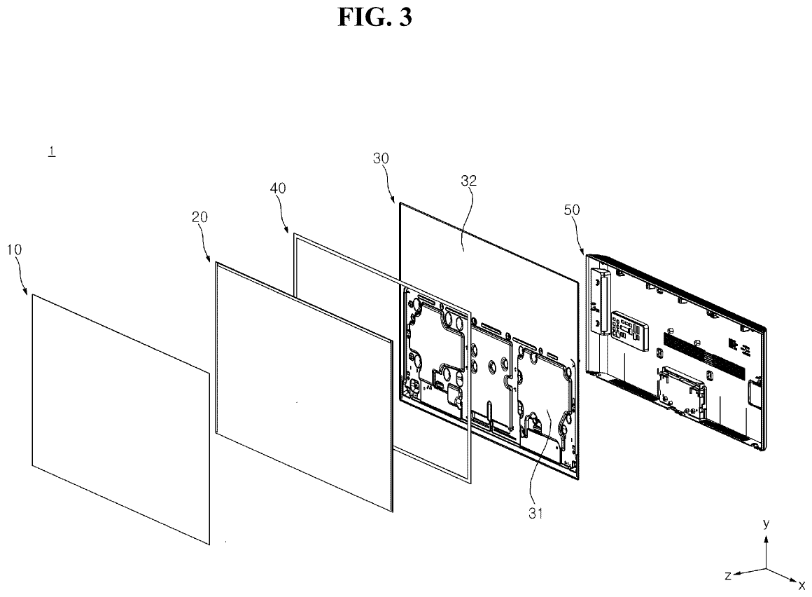

Referring to FIGS. 2 and 3, the display device 1 may include a display panel 10, a frame 30, and a side frame 40. Furthermore, the display panel 1 may include a plate 20 disposed behind the display panel 10, and a back cover 50 disposed behind the frame 30.

The display panel 10 may define the front surface of the display device 1, and may display an image on the front surface of the display device 1. The display panel 10 may divide an image into a plurality of pixels, and may control the color, brightness and chroma of each of the pixels, thereby outputting the image. The display panel 10 may be divided into an active area, in which an image is displayed, and an inactive area, in which an image is not displayed. The display panel 10 may generate light corresponding to red, green or blue in response to a control signal.

The plate 20 may be positioned behind the display panel 10. The plate 20 may be configured to have a shape corresponding to the overall shape of the display panel 10. The plate 20 may absorb heat generated from the display panel 10 during operation of the display device 1, and/or heat generated from a PCB 60 coupled to the frame 30, which will be described later. The heat absorbed into the plate 20 may be uniformly dispersed throughout the plate 20.

Accordingly, it is possible to prevent the occurrence of local hot spots on the display panel 10 due to the heat generated during operation of the display device 1. Here, the plate 20 may be referred to as an inner plate, a radiation plate or a heat sink. The plate 20 may increase the torsional rigidity and/or the bending rigidity of the display device 1. For example, the plate 20 may include a metal material, and the plate 20 may include a material having higher thermal conductivity than the frame 30. The plate 20 may include a composite material such as CFM (Carbon Fiber Material).

The frame 30 may be positioned behind the plate 20. The frame 30 may be configured to have a plate shape overall. A PCB 70 (not shown), on which a plurality of electronic elements are positioned, may be mounted on the frame 30. Here, the frame 30 may be referred to as a frame, a flat frame or a module cover. For example, the frame 30 may include a metal material.

The side frame 40 may define the lateral surface of the display device 1. The side frame 40 may extend along the edge of the frame 30. For example, the side frame 40 may have a quadrilateral shape overall. For example, the side frame 40 may include a metal material. The side frame 40 may include aluminum and may be produced through aluminum extrusion.

The back cover 50 may cover the rear surface of the frame 30. The back cover 50 may define the rear surface of the display device 1. The back cover 50 may include a middle cover 51 and a side cover 52. The middle cover 51 may be configured to have a plate shape overall and may be coupled to the side cover 52. The side cover 52 may extend along the edge of the middle cover 51 and may be disposed adjacent to the side frame 40. For example, the middle cover 51 may include a metal material, and the side cover 52 may include plastic.

A type in which the back cover 50 covers all the rear side of the frame may be referred to as a “full-back type”, and a type in which the back cover 50 covers the rear side of a lower part of the frame 30 may be referred to as a “half-back type”.

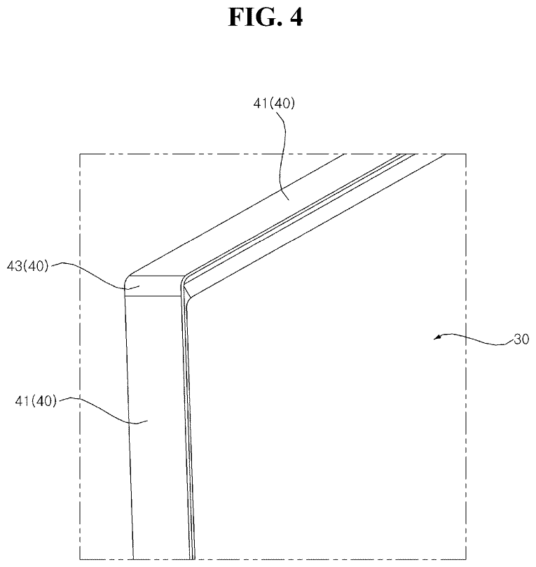

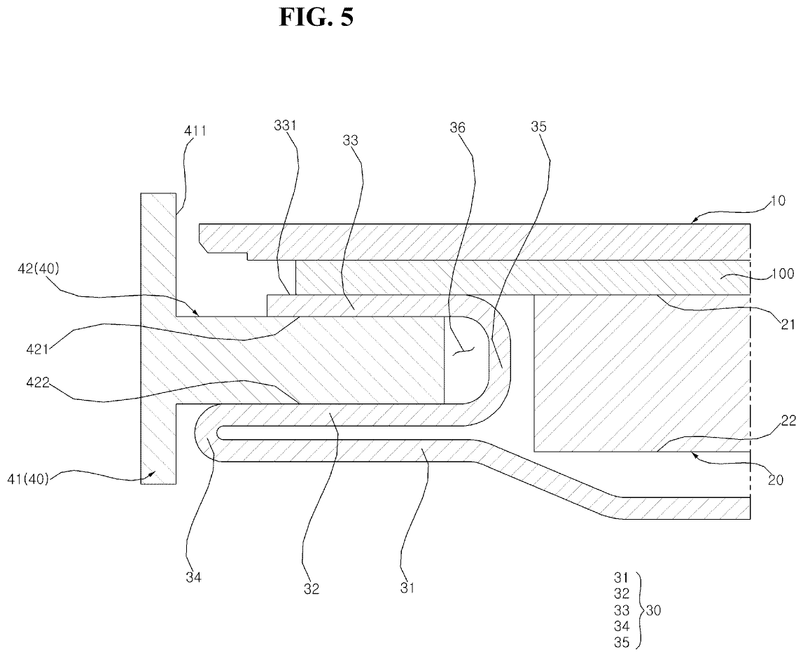

Referring to FIGS. 4 and 5, the frame 30 may be disposed behind the display panel 10, and a portion of the frame 30 may be exposed in a rearward direction.

The side frame 40 may extend along the edge of the display panel 10 to cover the edge of the display panel 10. The side frame 40 may include a first part 41 covering the edge of the display panel 10. The first part 41 may include four first parts 41 which extends long the upper, lower, right and left edges of the display panel 10, respectively. The four first parts 41 may cover the upper, lower, right and left edges of the display panel 10, respectively.

The side frame 40 may include a third part 43 disposed at the corner of the display device 1 (see FIG. 1) and may have a predetermined curvature. The third part 43 may be disposed at the corner of the display device 1 (see FIG. 1) and may be connected to the first part 41. The third part 43 may include four third parts 43 which are respectively disposed at a first corner C1 (see FIG. 1), a second corner C2 (see FIG. 1), a third corner C3 (see FIG. 1) and a fourth corner C4 (see FIG. 1) of the display device 1 (see FIG. 1). Each of the four third parts 43 may connect two different first parts 41 to each other.

Referring to FIG. 5, the guide frame 40 may include a second part 42 extending from the first part 41. The second part 42 may project from the inner lateral surface 411 that faces toward the inside of the display device 1 (see FIG. 1) and may extend in a direction extending the first part 41. For example, the first part 41 may be orthogonal to the second part 42. The first part 41 may have the form of a thin and long rectangular parallelepiped rod which is orthogonal to the first part 41. The first part 41 may be referred to as a “cover portion 41” or a “vertical portion 41”, and the second part 42 may be referred to as a “coupling portion 42” or a “horizontal portion 42”.

The frame 30 may include a rear part 31 disposed behind the display panel 10, and a middle part 32 which is bent forwards at the end of the rear part 31. The middle part 32 may face the rear part 31 and may be parallel to the rear part 31. The rear surface of the middle part 32 may be in contact with the front surface of the rear part 31. The frame 30 may include a first bent portion 34 connecting the rear part 31 to the middle part 32.

The frame 30 may include a front part 33 which is bent forwards at the end of the middle part 32. The front part 33 may be disposed behind the display panel 10 and may face the display panel 10. The front part 33 may be disposed so as to be spaced apart from the middle part 32 in a forward-and-rearward direction. The front surface 331 of the front part 33 may be parallel to the rear surface of the display panel 10. The frame 30 may include a second bent portion 35 connecting the middle part 32 to the front part 33.

The peripheral portion of the frame 30 may have an S shape overall when viewed in cross-section. The frame 30 may have an insertion groove 36 which is surrounded and defined by the front part 33, the middle part 32 and the second bent portion 35, and the second part 42 of the side frame 40 may be inserted into the insertion groove 36. The second part 42 may be inserted between the front part 33 and the middle part 32 and thus be coupled to the frame 30. Specifically, the front surface 421 may be in close contact with the rear surface of the front part 33, and the rear surface 422 of the second part 42 may be in close contact with the front surface of the middle part 32. The second part 42 may be forcibly fitted between the front part 33 and the middle part 32.

Accordingly, the side frame 40 may be coupled to the frame 30 without using an additional member, and a coupling member such as an adhesive sheet may be omitted, thereby reducing the thickness of the peripheral portion of the display device 1 (see FIG. 1) and production cost of the display device 1. In addition, the side frame 40 and the frame 30 may be separated from each other.

The plate 20 may be disposed between the display panel 10 and the frame 30. Specifically, the plate 20 may be disposed behind the display panel 10 and in front of the rear part 31. The plate 20 may face the second bent portion 35 and may be disposed adjacent to the second bent portion 35. At least a portion of an adhesive sheet 100 may be disposed between the plate 20 and the display panel 10 so as to couple the plate 20 to the display panel 10. The front surface 21 of the plate 20 may be flush with the front surface 331 of the front part 33. At least a portion of the adhesive sheet 100 may be disposed between the display panel 10 and the front part 33 so as to couple the display panel 10 to the front part 33. The rear surface of the adhesive sheet 100 may be adhered to the front surface 331 of the front part 33 and the front surface 21 of the plate 20, and the front surface of the adhesive sheet 100 may be adhered to the rear surface of the display panel 10.

The frame 30 and the side frame 40 may be made of different materials, thereby improving torsional rigidity of the peripheral portion of the display device 1 (see FIG. 1).

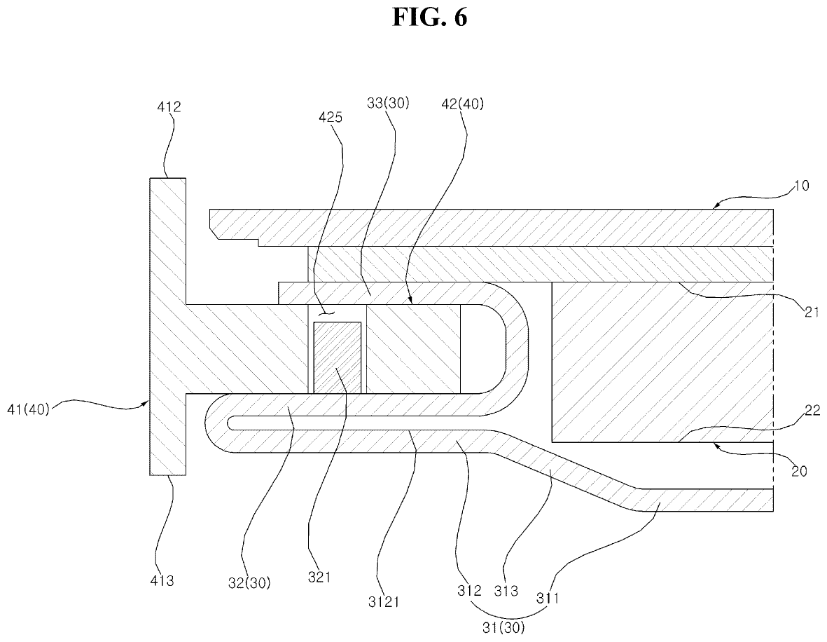

Referring to FIG. 6, the side frame 40 may have a hole 425 which is formed through the second part 42 in a forward-and-rearward direction. The second part 42 may extend along the edge of the display panel 10. The hole 425 may include a plurality of holes 425 which are spaced apart from each other in the lengthwise direction of the second part 42.

The frame 30 may include a projection 321 which projects forwards from the middle part 32. The middle part 32 may extend along the edge of the display panel 10. The projection 321 may include a plurality of projections 321 which are spaced apart from each other in the lengthwise direction of the middle part 32. The length of the projection 321 in a forward-and-rearward direction may be less than the distance between the front part 33 and the middle part 32. The projection 321 may be inserted into the hole 425, and thus the side frame 40 may be more firmly coupled to the frame 30. Each of the plurality of projections 321 may be inserted into a corresponding one of the plurality of holes 425.

The rear part 31 of the frame 30 may include a central portion 311 disposed behind the plate 20, and an edge portion 312 depressed forwards from the central portion 311. The rear part 31 may include a sloping portion 313 connecting the central portion 311 to the edge portion 312. The rear surface 22 of the plate 20 may be disposed behind the front surface 3121 of the edge portion 312 and in front of the central portion 311.

Because the plate 20 must have a predetermined thickness in order to efficiently radiate heat generated by the display panel 10, the central portion 311 of the rear part 31 must be spaced rearwards apart from the display panel 10 by a predetermined distance. Meanwhile, because the plate 20 is not disposed on the peripheral portion of the frame 30, the edge portion 312 of the rear part 31 may be disposed closer to the display panel 10 than the central portion 311.

The rear end 413 of the first part 41 of the side frame 40 may be positioned at a front side farther than the central portion 311 of the rear part 31. The front end 412 of the first part 41 may be positioned in front of the front surface of the display panel 10 or be flush with the front surface of the display panel 10. The length L2 of the first part 41 may be less than the distance L1 between the front surface of the display panel 10 and the rear surface of the central portion 311 in a forward-and-rearward direction. Accordingly, the thickness of the peripheral portion of the display device 1 (see FIG. 1) may be less than the thickness of the central portion of the display device 1 (see FIG. 1).

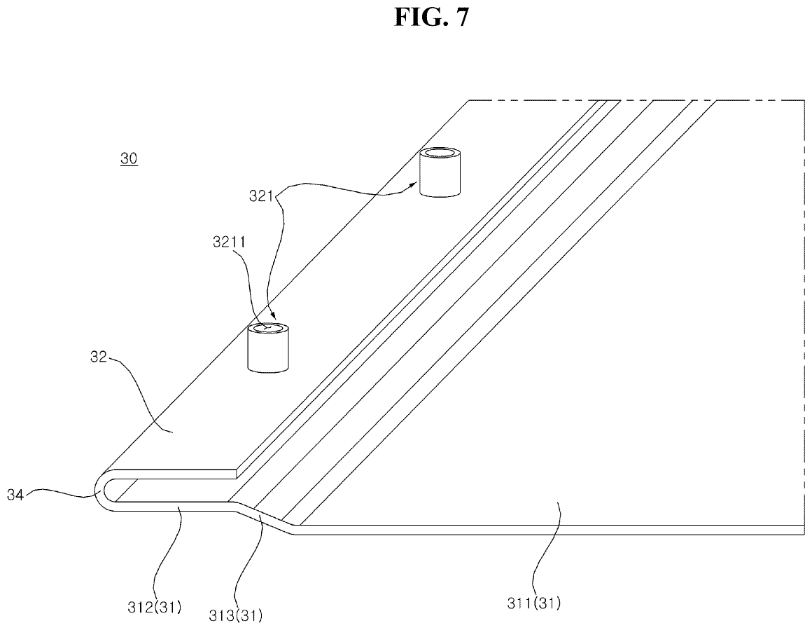

Referring to FIG. 7, the frame 30 may include the rear part 31, and the middle part 32 which is bent forwards at the end of the rear part 31. The frame 30 may include the first bent portion 34 connecting the rear part 31 to the middle part 32. The frame 30 may include the projection 321 which projects forwards from the middle part 32. The projection 321 may be formed by pressing the rear surface of the middle part 32 forwards. The projection 321 may have a pipe shape overall. For example, the projection 321 may have a cylindrical shape overall. The projection 321 may be perforated in a forward-and-rearward direction, thereby forming a through hole.

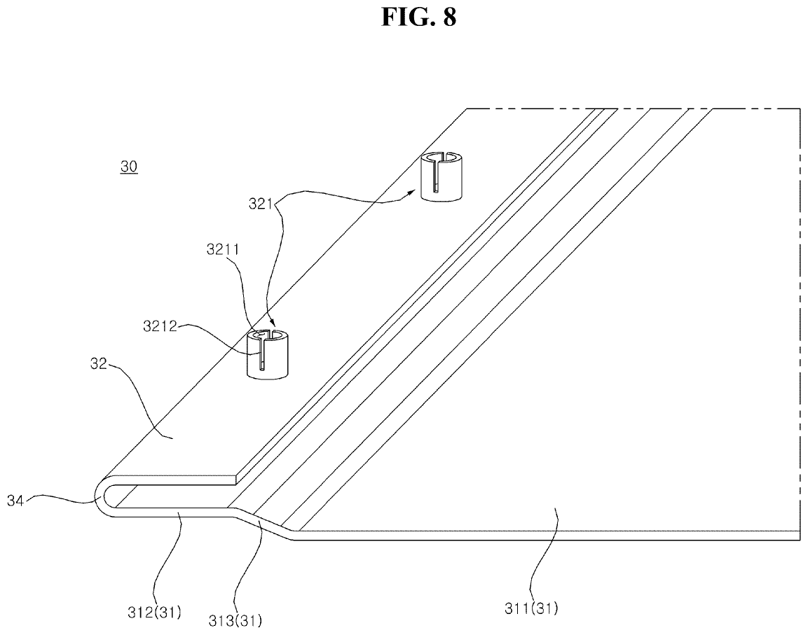

Referring to FIG. 8, the projection 321 may have a slit 3212 which is formed by cutting the projection 321 rearwards from the front end of the projection 321. Accordingly, when a rearward pressure is applied to the front end of the projection 321, the front end of the projection 321 may be easily bent in a radial direction of the projection 321.

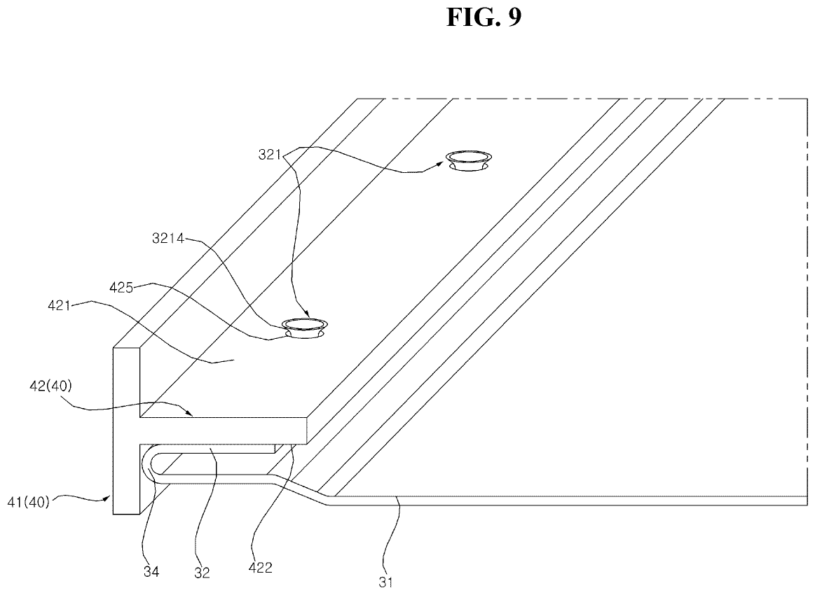

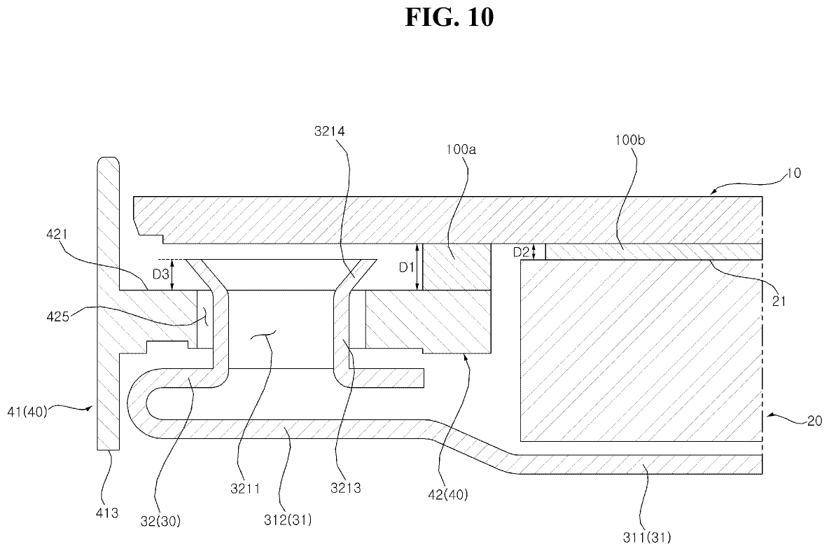

Referring to FIGS. 9 and 10 together, the side frame 40 may have the hole 425 which is formed through the second part 42 in a forward-and-rearward direction, and the projection 321 may be inserted into the hole 425. The length of the projection 321 in a forward-and-rearward direction may be greater than the length of the second part 42 in a forward-and-rearward direction, and the front end of the projection 321 may project forwards from the second part 42. The projection 321 may include an insertion portion 3213 disposed in the hole 425, and a catch portion 3214 which projects forwards from the second part 42 and overlaps the second part 42 in a forward-and-rearward direction.

The middle part 32 may be in contact with the second part 42. Specifically, the middle part 32 may be parallel to the second part 42, and the front surface of the middle part 32 may be in contact with the rear surface 422 of the second part 42. The second part 42 may be disposed on the front surface of the middle part 32, and the projection 321 may be inserted into the hole 425 formed in the second part 42. Thereafter, a pressure may be applied to the front end of the projection 321 so as to form the catch portion 3214 in the front end of the projection 321. In other words, by inserting the projection 321 into the hole 425 and expanding the front end of the projection 321 in a direction intersecting the lengthwise direction of the projection 321, the projection 321 may catch on the second part 42 and thus the side frame 40 may be coupled to the frame 30. For example, the catch portion 3214 may be formed by pressing the front end of the projection 321 rearwards.

The insertion portion 3213 of the projection 321 that is inserted into the hole 425 may have a cylindrical shape overall, and the outer diameter of the insertion portion 3213 may be smaller than the diameter of the hole 425. The projection 321 may include the catch portion 3214 which is formed at the front end of the projection 321 and is positioned in front of the second part 42 so as to overlap the second part 42. For example, the catch portion 3241 may have a truncated cone shape the diameter of which gradually increases forwards, and the outer diameter of the catch portion 3214 may be larger than the diameter of the hole 425.

Alternatively, in another embodiment of the present disclosure, the catch portion 3214 may be bent outwards in a radial direction from the front end of the insertion portion 3213 and may catch on the front surface 421 of the second part 42.

The side frame 40 may be coupled to the display panel 10. Specifically, a first adhesive sheet 100a may be disposed between the second part 42 and the display panel 10 such that the front surface of the first adhesive sheet 100a is adhered to the rear surface of the display panel 10 and the rear surface of the first adhesive sheet 100a may be adhered to the front surface of the second part 42. The thickness D1 of the first adhesive sheet 100a may be greater than the distance D3 between the front end of the projection 321 and the second part 42.

The display panel 10 may be coupled to the plate 20. Specifically, a second adhesive sheet 100b may be disposed between the display panel 10 and the plate 20 such that the front surface of the second adhesive sheet 100b is adhered to the rear surface of the display panel 10 and the rear surface of the second adhesive sheet 100b may be adhered to the front surface 21 of the plate 20. The thickness D1 of the first adhesive sheet 100a may be greater than the thickness D2 of the second adhesive sheet 100b. Because the catch portion 3214 of the projection 321 projects forwards from the second part 42, the thickness D1 of the first adhesive sheet 100a may increase and thus the thickness D1 of the first adhesive sheet 100a may be greater than the thickness D2 of the second adhesive sheet 100b.

The rear end 413 of the first part 41 may be positioned in front of the central portion 311 of the rear part 31.

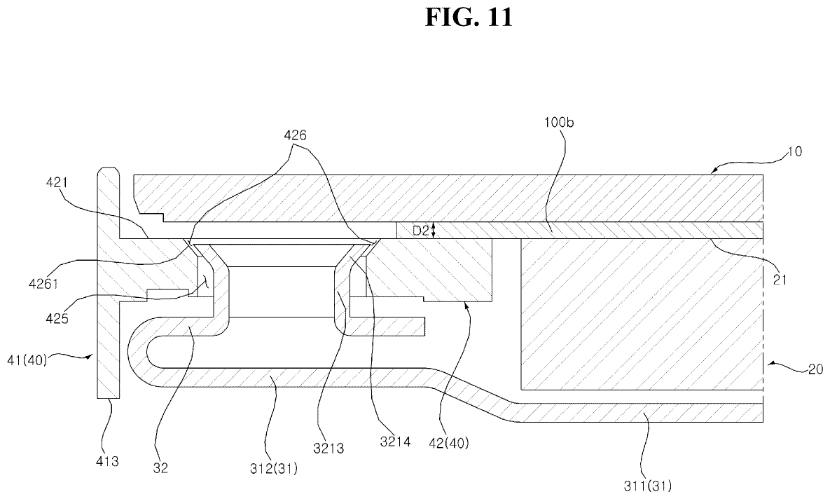

Referring to FIG. 11, the second part 42 may have a recess portion 426 which is depressed rearwards from the front surface 421 of the second part 42. The recess portion 426 may be formed around the hole 425 and may communicate with the hole 425. The end of the recess portion 3214 of the projection 321 may be disposed in the recess portion 426 in a radial direction of the projection 321. The front end of the catch portion 3214 may be disposed in the recess portion 426 so as not to project forwards from the second part 42.

For example, a chamfer 4261 may be formed at the boundary of the hole 425 on the front surface 421 of the second part 42, and the space defined by an imaginary surface, which is formed by forward extension of the boundary of the hole 425, and the chamfer 4261 may be defined as the “recess portion 426”. The chamfer 4261 may be referred to as a “chamfered surface 4261” or a “recess surface 4261. The catch portion 3214 may be in contact with the chamfer 4261 and may catch on the chamfer 4261, with the result that the side frame 40 may be coupled to the frame 30.

The front surface 21 of the plate 20 and the front surface 421 of the second part 42 may be positioned so as to be flush with each other. The second adhesive sheet 100b may be disposed between the display panel 10 and the plate 20 and may extend to the front side of the second part 42. The front surface of the second adhesive sheet 100b may be adhered to the rear surface of the display panel 10, and the rear surface of the second adhesive sheet 100b may be adhered to the front surface 21 of the plate 20 and the front surface 421 of the second part 42. Accordingly, because the catch portion 3214 does not project forwards from the front surface 421 of the second part 42, it is possible to reduce the distance between the front surface 421 of the second part 42 and the rear surface of the display panel 10. Specifically, the distance between the front surface 421 of the second part 42 and the rear surface of the display panel 10 may be substantially equal to the thickness D2 of the second adhesive sheet 100b.

The rear end 413 of the first part 41 may be positioned in front of the central portion 311 of the rear part 31.

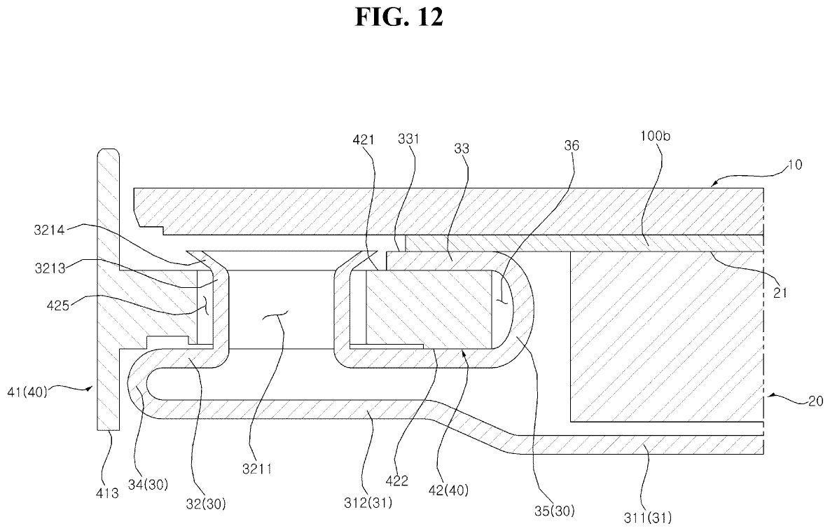

Referring to FIGS. 10 and 12 together, the frame 30 may include the front part 33 which is bent forwards at the end of the middle part 32 and faces the display panel 10. The middle part 32 and the front part 33 may be connected to each other via the second bent portion 35. The frame 30 may have the insertion groove 36 defined by the middle part 32, the front part 33 and the second bent portion 35. The second part 42 may be inserted into the insertion groove 36, thereby more firmly coupling the side frame 40 to the frame 30. The front end of the catch portion 3214 may be positioned behind the front surface 331 of the front part 33 or be substantially flush with the front surface 331 of the front part 33.

The front surface 331 of the front part 33 may be substantially flush with the front surface 21 of the plate 20, and the second sheet 100b may be disposed between the display panel 10 and the plate 20 and may extend to the front side of the front surface 331 of the front part 33. The front surface of the second adhesive sheet 100b may be adhered to the rear surface of the display panel 10, and the rear surface of the second adhesive sheet 100b may be adhered to the front surface 21 of the plate 20 and the front surface 331 of the front part 33.

The second part 42 may be disposed in front of the middle part 32, the projection 321 may be inserted into the hole 425, and a pressure may be applied to the front side of the projection 321. Consequently, the front end of the projection 321 may be expanded in a radial direction of the projection 321, thereby forming the catch portion 3214. Furthermore, the front surface 421 of the second part 42 may catch on the catch portion 3214, and the rear surface 422 of the second part 42 may come into close contact with the front surface of the middle part 32, thereby coupling the side frame 40 to the frame 30. Furthermore, the rear surface of the front part 33, which is bent forwards at the end of the middle part 32, may come into close contact with the front surface 421 of the second part 42, thereby more firmly coupling the side frame 40 to the frame 30. The rear end 413 of the first part 41 may be positioned in front of the central portion 311 of the rear part 31.

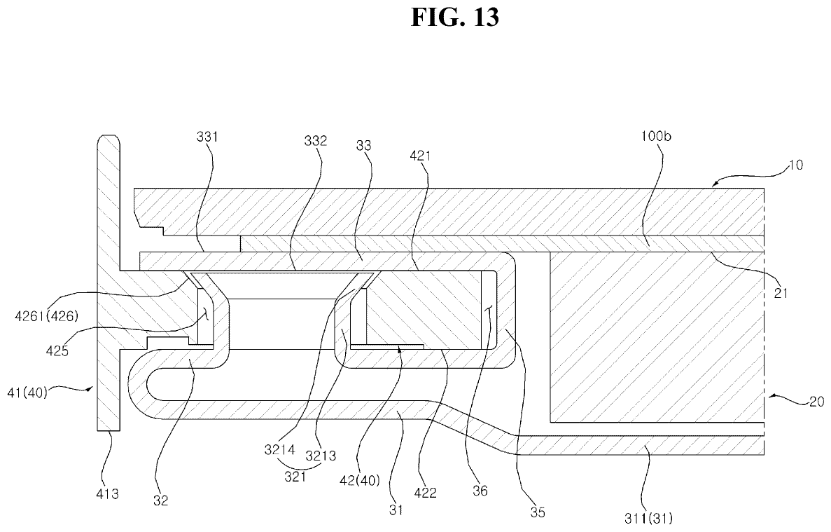

Referring to FIGS. 11 and 13 together, the frame 30 may include the front part 33 which is bent forwards at the end of the middle part 32 and faces the display panel 10. The middle part 32 and the front part 33 may be connected to each other via the second bent portion 35. The frame 30 may have the insertion groove 36 which is defined by the middle part 32, the front part 33 and the second bent portion 35. The second part 42 may be inserted into the insertion groove 36 and thus the side frame 40 may be more firmly coupled to the frame 30.

The front part 33 may extend to the front side of the projection 321 and may cover the front end of the projection 321. The front end of the catch portion 3214 does not project forwards from the front surface 421 of the second part 42 and thus the rear surface 332 of the front part 33 may be in closed contact with the front surface 421 of the second part 42.

The second part 42 may be disposed in front of the middle part 32, and the projection 321 may be inserted into the hole 425, and a pressure may be applied to the front side of the projection 321. Consequently, the front end of the projection 321 may be expanded in a radial direction of the projection 321, thereby forming the catch portion 3214. Furthermore, the catch portion 3214 may catch on the recess portion 426 in the second part 42, and the rear surface 422 of the second part 42 may be in closed contact with the front surface of the middle part 32, thereby coupling the side frame 40 to the frame 30. In addition, the rear surface 332 of the front apart 33 which is bent forwards at the end of the middle part 32 may be in close contact with the front surface 421 of the second part 42, thereby more firmly coupling the side frame 40 to the frame 30. The rear end 413 of the first part 41 may be positioned in front of the central portion 311 of the rear part 31.

The front surface 331 of the front part 31 may be substantially flush with the front surface 21 of the plate 20, and the second adhesive sheet 100b may be disposed between the display panel 10 and the plate 20 and may extend to the front side of the front surface 331 of the front part 33. The front surface of the second adhesive sheet 100b may be adhered to the rear surface of the display panel 10, and the rear surface of the second adhesive sheet 100b may be adhered to the front surface 21 of the plate 20 and the front surface 331 of the front part 33.

Referring to FIGS. 1 to 13, the display device 1 according to an aspect of the present disclosure may include: the display panel 10; the frame 30 disposed behind the display panel 10; and the side frame 40 disposed along the edge of the frame 30, wherein the side frame 40 may include: the first part 41 covering the edge of the frame 30; and the second part 42 intersecting the first part 41 and disposed between the frame 30 and the display panel 10, wherein the frame 30 may include: the rear part 31 disposed behind the second part 42; the middle part 32 which is bent from the end of the rear part 31 and which faces the front surface of the rear part 31; and the front part 33 which is bent from the end of the middle part 32 and which faces the display panel 10, and wherein the second part 42 may be inserted into the middle part 32 and the front part 33.

The display device 1 may further include the plate 20 disposed between the display panel 10 and the rear part 31, and wherein the front surface 21 of the plate 20 may be positioned on the same plane as the front surface 331 of the front part 33.

The display device 1 may further include the adhesive sheet 100 which is disposed between the front part 33 and the display panel 10 and which is configured to couple the front part 33 and the plate 20 to the display panel 10.

The rear part 31 may include: the central portion 311 disposed behind the plate 20; and the edge portion 312 disposed behind the second part 42 and depressed forward from the central portion 311, and the rear end 413 of the first part 41 may be positioned in front of the central portion 311 of the rear part 31.

The second part 42 may have the hole 425 which is formed through the second part 42 in a front-rear direction, and the frame 30 may further include the projection 321 which projects forward from the middle part 32 and is inserted into the hole 425.

The display device 1 according to an aspect of the present disclosure may include: the display panel 10; the frame 30 disposed behind the display panel 10; and the side frame 40 disposed along the edge of the frame 30, wherein the side frame 40 may include: the first part 41 covering the edge of the frame 30; and the second part 42 which intersects the first part 41, and which is disposed between the frame 30 and the display panel 10, and which comprises a hole 425 formed through the second part 42 in a front-rear direction, and wherein the frame 30 may include: a rear part 31 disposed behind the second part 42; a middle part 32 which is bent from the end of the rear part 31 and which faces a front surface of the rear part 31; and a projection 321 which projects forward from the middle part 32 and is inserted into the hole 425 in the second part 42.

The projection 321 may include: an insertion portion 3213 which has a tubular shape extending in the front-rear direction, and which is inserted into the hole 425; and the catch portion 3214 formed at a front end of the insertion portion 3213 and overlapping with the second part 42 in the front-rear direction.

The outer diameter of the catch portion 3214 may be larger than the diameter of the hole 425.

The second part 42 may further include the recess portion 426 which is depressed from the front surface 421 of the second part 42 around the hole 425, wherein the hole 425 is positioned on the recessed portion 426, and wherein the catch portion 3214 may be disposed on the recess portion 426.

The front end of the projection 321 may be disposed behind the front surface 421 of the second part 42.

The display device 1 may further include a plate 20 disposed between the display panel 10 and the rear part 31, and wherein a front surface 21 of the plate 20 may be positioned on the same plane as the front surface 421 of the second part 42.

The rear part 31 may include: the central portion 311 disposed behind the plate 20; and the edge portion 312 which is depressed forward from the central portion 311 and which is disposed behind the second part 42, and wherein a rear end 413 of the first part 41 may be disposed in front of the central portion 311.

The frame 30 may further include the front part 33 which is bent from the end of the middle part 32 and which faces the display panel 10, and wherein the second part 42 may be inserted between the middle part 32 and the front part 33.

The side frame 40 may extend along one side of the display panel 10, wherein the hole 425 in the second part 42 may have a plurality of holes 425 which are spaced apart from each other in the longitudinal direction of the side frame 40, and the projection 321 may include a plurality of projections 321 which are respectively inserted into the plurality of holes 425.

The projection 321 may have a slit which is formed by partially cutting the projection rearward from a front end of the projection 321.

The display device 1 according to an aspect of the present disclosure may include: a display panel 10; a frame 30 disposed behind the display panel 10; and a side frame 40 disposed along the edge of the frame 30, wherein the frame 30 may include: a front part 33 which faces the display panel 10; and a middle part 32 which is bent rearward from an end of front part 33 and which overlaps with the front part 33 in a front-rear direction, and wherein the side frame 40 may include: a first part 41 covering the edge of the display panel 10; and a second part 42 which extends from the first part 41 and which is inserted between the front part 33 and the middle part 32.

The frame 30 may further include: the rear part 31 which is bent rearward from an end of the middle part 32 and which overlaps with a rear surface of the middle part 32, wherein the rear part 31 may include: an edge portion 312 disposed behind the middle part 32; and a central portion 311 depressed rearward from the edge portion 312.

The rear end 413 of the first part 41 may be disposed in front of the central portion 311 of the rear part 31.

The front surface 331 of the front part 33 may be parallel to the rear surface of the display panel 10.

The display device 1 may further include an adhesive sheet 100 disposed between the front part 33 and the display panel 10 and configured to couple the front part 33 to the display panel 10.

The effects of the display device according to the present disclosure will be described.

According to at least one of the embodiments of the present disclosure, it is possible to provide a structure configured to couple the side frame to the frame without using an additional adhesive member.

According to at least one of the embodiments of the present disclosure, it is possible to provide a structure configured to detachably couple the side frame to the frame.

According to at least one of the embodiments of the present disclosure, it is possible to provide a display device having a peripheral portion having a thin thickness.

According to at least one of the embodiments of the present disclosure, it is possible to provide a display device which includes a side portion having improved rigidity.

According to at least one of the embodiments of the present disclosure, it is possible to provide a display device having improved torsional rigidity.

The additional scope of applicability of the present disclosure will be apparent from the above detailed description. However, those skilled in the art will appreciate that various modifications and alterations are possible, without departing from the idea and scope of the present disclosure, and therefore it should be understood that the detailed description and specific embodiments, such as the preferred embodiments of the present disclosure, are provided only for illustration.

Certain embodiments or other embodiments of the disclosure described above are not mutually exclusive or distinct from each other. Any or all elements of the embodiments of the disclosure described above may be combined with each other in configuration or function.

For example, a configuration “A” described in one embodiment of the disclosure and the drawings and a configuration “B” described in another embodiment of the disclosure and the drawings may be combined with each other. That is, even if the combination of the configurations is not explicitly described, the combination is possible except in the case where it is stated that the combination is impossible.

Although embodiments have been described with reference to a number of illustrative embodiments thereof, it should be understood that numerous other modifications and embodiments that fall within the scope of the principles of this disclosure can be devised by those skilled in the art. More particularly, various variations and modifications are possible in the component parts and/or arrangements within the scope of the disclosure, the drawings and the appended claims. In addition to variations and modifications in the component parts and/or arrangements, alternative uses will also be apparent to those skilled in the art.

What is claimed is:

1. A display device comprising:
a display panel;
a frame disposed behind the display panel;
a side frame disposed along an edge of the frame,
wherein the side frame comprises:
a first part covering the edge of the frame; and
a second part intersecting the first part and disposed between the frame and the display panel,
wherein the frame comprises:
a rear part disposed behind the second part;
a middle part which is bent from an end of the rear part and which faces a front surface of the rear part; and
a front part which is bent from an end of the middle part and which faces the display panel, and
wherein the second part is inserted between the middle part and the front part.

2. The display device of claim 1, further comprising a plate disposed between the display panel and the rear part,
wherein a front surface of the plate is positioned on the same plane as a front surface of the front part.

3. The display device of claim 2, further comprising an adhesive sheet disposed between the front part and the display panel and configured to couple the front part and the plate to the display panel.

4. The display device of claim 2, wherein the rear part comprises:
a central portion disposed behind the plate; and
an edge portion disposed behind the second part and depressed forward from the central portion, and
wherein a rear end of the first part is positioned in front of the central portion of the rear part.

5. The display device of claim 1, wherein the second part comprises a hole formed through the second part in a front-rear direction, and
wherein the frame further comprises a projection which projects forward from the middle part and is inserted into the hole.

6. A display device comprising:
a display panel;
a frame disposed behind the display panel; and
a side frame disposed along an edge of the frame,
wherein the side frame comprises:
a first part covering the edge of the frame; and
a second part intersecting the first part and disposed between the frame and the display panel, the second part comprising a hole formed through the second part in a front-rear direction, and
wherein the frame comprises:
a rear part disposed behind the second part;
a middle part which is bent from an end of the rear part and which faces a front surface of the rear part; and
a projection projecting forward from the middle part and inserted into the hole in the second part.

7. The display device of claim 6, wherein the projection comprises:
an insertion portion which has a hollow tubular shape extending in the front-rear direction and which is inserted into the hole; and
a catch portion formed at a front end of the insertion portion and overlapping with the second part in the front-rear direction.

8. The display device of claim 7, wherein an outer diameter of the catch portion is larger than a diameter of the hole.

9. The display device of claim 7, wherein the second part further comprises a recess portion which is depressed from a front surface of the second part around the hole,
wherein the hole is positioned on the recess portion, and
wherein the catch portion is positioned on the recess portion.

10. The display device of claim 9, wherein a front end of the projection is positioned behind the front surface of the second part.

11. The display device of claim 10, further comprises a plate disposed between the display panel and the rear part,
wherein a front surface of the plate is positioned on the same plane as the front surface of the second part.

12. The display device of claim 11, wherein the rear part comprises:
a central portion disposed behind the plate; and
an edge portion which is depressed forward from the central portion and which is positioned behind the second part, and
wherein a rear end of the first part is disposed in front of the central portion.

13. The display device of claim 7, wherein the frame further comprises a front part which is bent from an end of the middle part and which faces the display panel, and
wherein the second part is inserted between the middle part and the front part.

14. The display device of claim 6, wherein:
the side frame extends along one side of the display panel,
the hole in the second part comprises a plurality of holes which are spaced apart from each other in a longitudinal direction of the side frame, and
the projection comprises a plurality of projections which are respectively inserted into the plurality of holes.

15. The display device of claim 7, wherein the projection comprises a slit which is formed by partially cutting the projection rearward from a front end of the projection.

16. A display device comprising:
a display panel;
a frame disposed behind the display panel;
a side frame disposed along an edge of the frame,
wherein the frame comprises:
a front part which is positioned at the rear of the display panel; and
a middle part which is bent rearward from an end of the front part and which overlaps with the front part in a front-rear direction, and
wherein the side frame comprises:
a first part covering an edge of the display panel; and
a second part which extends from the first part and is inserted between the front part and the middle part.

17. The display device of claim 16, wherein the frame further comprises a rear part which is bent rearward from an end of the middle part and which overlaps with a rear surface of the middle part,
wherein the rear part comprises:
an edge portion disposed behind the middle part; and
a central portion depressed rearward from the edge portion.

18. The display device of claim 17, wherein a rear end of the first part is disposed in front of the central portion of the rear part.

19. The display device of claim 16, wherein a front surface of the front part is parallel to a rear surface of the display panel.

20. The display device of claim 19, further comprising an adhesive sheet disposed between the front part and the display panel and configured to couple the front part to the display panel.
